(19) United States
(12) Patent Application Publication
(10) Pub. No.: US 2023/0002884 A1
(43) Pub. Date: Jan. 5, 2023

(54) SYSTEMS AND METHODS FOR FILM DEPOSITION

(71) Applicant: CORNING INCORPORATED, CORNING, NY (US)

(72) Inventors: Chang-gyu Kim, Suwon-si (KR); Jeonghong Oh, Cheonan-si (KR); Jung-Hun Yun, Seoul City (KR)

(21) Appl. No.: 17/779,231

(22) PCT Filed: Nov. 19, 2020
(86) PCT No.: PCT/US2020/061151

§ 371 Date: May 24, 2022

Related U.S. Application Data
(60) Provisional application No. 62/941,256, filed on Nov. 27, 2019.

(51) Int. Cl. C23C 14/50; C23C 14/54

(52) U.S. Cl. CPC C23C 14/505; C23C 14/542

(57) ABSTRACT

A system is described herein for film deposition includes a drum; a motor configured to rotate the drum in a direction of rotation; a target including a target material; and a holder attached to the drum. The holder is configured to accommodate a substrate and to expose the substrate to free particles of the target material sputtered from the target, and the holder has an asymmetric shape.

### CLAIM OF PRIORITY

This application claims the benefit of priority under 35 U.S.C. § 119 of U.S. Provisional Application Ser. No. 62/941,256, filed on Nov. 27, 2019, the content of which is relied upon and incorporated herein by reference in its entirety.

### FIELD

This disclosure relates holders for drum coaters, and to devices, systems and methods relating to holders for drum coaters.

### BACKGROUND

Drum coaters can be used for film deposition. Holders for substrates can be attached to drums of drum coaters, and a film can be deposited or developed on the substrates. In certain implementations, it can be desirable to deposit or develop a film for which at least some portions have a relatively uniform thickness.

### SUMMARY

Disclosed herein are devices, systems and methods relating to film deposition.

In certain comparative systems, a drum coater includes multiple holders attached to surfaces of a drum. The holders have substantially flat surfaces. The drum of the drum coater may rotate (e.g., may be rotated by a motor) to expose, in turn, the substantially flat surfaces of the holders to a target from which a target material is sputtered. The sputtered target material deposits on the substantially flat surfaces to form films on the substantially flat surfaces.

In the comparative systems, the drum may have a polygon shape, and the holders may be attached to respective sides of the polygon. As the drum rotates, certain portions of substantially flat surfaces of the substrates may be brought closer to the target than other portions of the substantially flat surfaces of the substrates. The film may develop to be thicker on the portions of the substantially flat surfaces of the substrates that are brought closer to the target, and relatively less thick on the portions of the substantially flat surfaces of the substrates that are brought less close to the target. This can result in the films having less uniform thicknesses than may be desired for certain applications.

In some embodiments disclosed herein, a holder having an asymmetric shape (e.g., an asymmetric cross-section) is implemented. The asymmetric shape of the holder may be defined at least in part by certain portions of the holder being thicker than other portions of the holder. Such a holder may be referred to herein as an “asymmetric holder.” The asymmetric holder may include a base portion attached to the drum at a bottom surface of the holder. The base portion may have a substantially flat top surface opposite to the bottom surface. The asymmetric holder may include a top portion having a substantially non-uniform thickness. In such a system, certain portions of the base portion may be brought relatively less close to the target by the rotation of the drum, and certain other portions of the base portion may be brought relatively closer to the target by the rotation of the drum. The certain portions of the base portion that are brought relatively less close to the target by the rotation of the drum may correspond to (may be disposed below, or may underlie) relatively thicker portions of the top portion, and the certain portions of the base portion that are brought relatively closer to the target by the rotation of the drum may correspond to (may be disposed below, or may underlie) relatively thinner portions of the top portion. Thus, the asymmetry of the top portion of the asymmetric holder may at least somewhat account for variations in how close the portions of the base portion are brought to the target by the rotation of the drum, which can provide for a film deposition process that provides films having a more uniform thickness than the comparative systems described above.

In some embodiments, according to a first aspect, a system for film deposition includes a drum; a motor configured to rotate the drum in a direction of rotation; a target including a target material; and a holder attached to the drum. The holder is configured to accommodate a substrate and to expose the substrate to free particles of the target material sputtered from the target, and the holder has an asymmetric shape.

In some embodiments, the holder has a first surface and a second surface opposite to the first surface, the first surface is attached to the drum, and the holder includes: a first portion that is continuous and that includes a first edge of the holder; and a second portion. The second portion of the holder is thicker than the first portion of the holder.

In some embodiments, the direction of rotation is a direction extending from the first portion of the holder to the second portion of the holder.

In some embodiments, the second portion of the holder is a central portion, and the central portion of the holder is attached to and contacts the drum.

In some embodiments, the holder includes a third portion that is continuous and that includes a second edge of the holder opposite to the first edge of the holder.

In some embodiments, the holder has a first surface attached to the drum and a second surface, and the second surface is inclined at an angle between t degrees and 3 degrees relative to the first surface.

In some embodiments, the drum has a polygon shape having a plurality of edges and a plurality of corners, and the motor is configured to rotate the drum such that a shortest distance between one of the corners and the target during one revolution of the drum is less than a shortest distance between one of the edges and the target during the one revolution of the drum.

In some embodiments, according to a second aspect, a system for film deposition includes: a drum; a motor configured to rotate the drum in a direction of rotation; a target comprising a target material; and a holder attached to the drum, the holder configured to accommodate a substrate and to expose the substrate to free particles of the target material sputtered from the target. The holder has a first surface and a second surface opposite to the first surface, and a first edge and a second edge opposite to the first edge. The holder includes a first portion that is continuous and that includes the first edge of the holder, a second portion, and a third portion that is continuous and that includes the second edge of the holder, and the second portion is located between the first portion of the holder and the third portion of the holder. A distance between the drum and a portion of the second surface located at the second portion of the holder is longer than a distance between the drum and a portion of the second surface located at one of the first edge or the second edge of the holder.

In some embodiments, the second portion of the holder is thicker than the first portion of the holder, and the second portion of the holder is thicker than the third portion of the holder.

In some embodiments, the second surface of the holder is inclined, at a first angle, between the first portion of the holder and the second portion of the holder, the second surface of the holder is inclined, at a second angle different from the first angle, between the second portion of the holder and the third portion of the holder, the first surface of the holder is substantially flat, and the first angle and the second angle are relative to the first surface of the holder.

In some embodiments, the first angle is larger than 0 degrees and less than 3 degrees.

In some embodiments, a distance along the second surface between the first edge of the holder and a thickest portion of the second portion of the holder is between 250 millimeters (mm) and 350 mm.

In some embodiments, the second angle is between 0 degrees and 20 degrees.

In some embodiments, the system further includes the substrate, wherein the substrate is disposed on the first portion of the holder and the second portion of the holder.

In some embodiments, according to a third aspect, a method for depositing film using a system for film deposition includes attaching a holder to a drum, the holder having an asymmetric shape; attaching a substrate to the holder; rotating the drum using a motor such that the substrate faces a target including a target material; and sputtering particles of the target material from the target on to the substrate.

In some embodiments, the holder has a first surface and a second surface opposite to the first surface, and the holder includes: a first portion located at a first edge of the holder; and a second portion. The second portion of the holder is thicker than the first portion of the holder, and the holder is attached to the drum via the first surface of the holder.

In some embodiments, the drum is rotated in a direction of rotation, and the direction of rotation, at a point where the holder is attached to the drum, is from the first portion of the holder to the second portion of the holder.

In some embodiments, the second portion of the holder is a central portion of the holder.

In some embodiments, the holder includes a third portion located at a second edge of the holder opposite to the first edge of the holder, and the second portion of the holder is thicker than the third portion of the holder.

In some embodiments, the holder has a first surface attached to the drum and a second surface, and the second surface is inclined at an angle between 0 degrees and 3 degrees relative to the first surface.

In some embodiments, according to a fourth aspect, a drum coater includes a holder configured to accommodate a substrate and to expose the substrate to free particles of a target material. The holder includes a first portion having a top surface at 0 degrees from a horizontal, and a second portion disposed on the top surface of the first portion. The second portion has a first surface inclined at a first angle relative to the top surface of the first portion, and a second surface inclined at a second angle relative to the top surface of the first portion. The first angle is in a range of 90 degrees to 1 degree, and the second angle is in a range of 90 degrees to 1 degree.

In some embodiments, the first angle is in a range of 1 degree to 2 degrees.

In some embodiments, the second angle is in a range of 1 degree to 20 degrees.

In some embodiments, the holder is configured to expose the substrate to the free particles of the target material such that a film of the target material is grown on the substrate, the film having a thickness uniformity of 2% or less.

In some embodiments, a length of the first surface of the second portion and a length of the second surface of the second portion sum to 400 millimeters (mm) or less.

It is to be understood that the foregoing description and the following description are merely exemplary, and are intended to provide an overview or framework to understanding the claimed subject matter.

### BRIEF DESCRIPTION OF THE DRAWINGS

The details of one or more embodiments are set forth in the accompanying drawings and the description below. Other features, aspects, and advantages of the disclosure will become apparent from the description, the drawings, and the claims. In the drawings, like reference numerals are used throughout the various views to designate like components.

FIG. 1 is a depiction of holders hung on a drum, according to at least one embodiment.

FIG. 2A illustrates an example of a film deposition system, according to at least one embodiment.

FIG. 2B is a flow chart describing an example of a method of film deposition, according to at least one embodiment.

FIG. 3A and FIG. 3B illustrate rotation of a drum of a film deposition system, according to at least one embodiment.

FIG. 4 illustrates respective distances between portions of a holder and a target of a film deposition system, according to at least one embodiment.

FIG. 5A illustrates a configuration of a comparative holder.

FIG. 5B illustrates an example configuration of holder, according to at least one embodiment.

FIG. 5C illustrates experimentally measured thicknesses for films developed using the holders shown in FIG. 5A and FIG. 5B.

FIG. 6A illustrates example configurations of holders, according to embodiments of the present disclosure.

FIG. 6B illustrates experimentally measured thicknesses for films developed using the holders shown in FIG. 6A.

FIG. 7A illustrates example configurations of holders, according to embodiments of the present disclosure.

FIG. 7B illustrates experimentally measured thicknesses for films developed using the holders shown in FIG. 7A.

FIG. 8 illustrates an example of substrates disposed on a holder, according to embodiments of the present disclosure.

FIG. 9 illustrates example configurations of surfaces of a holder, according to embodiments of the present disclosure.

### DETAILED DESCRIPTION

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other appropriate embodiment(s).

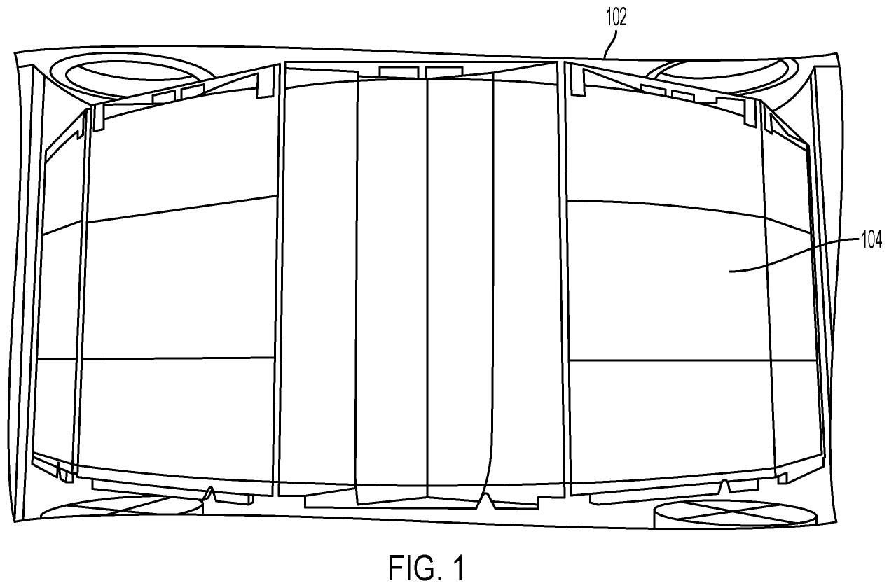

FIG. 1 is a depiction of holders hung on a drum, according to at least one embodiment. The depiction shows a plurality of holders 104 hung on a drum 102. Substrates can be mounted on the holders 104. The drum 102 is configured to rotate, thereby exposing the substrates to a target from which target material is sputtered.

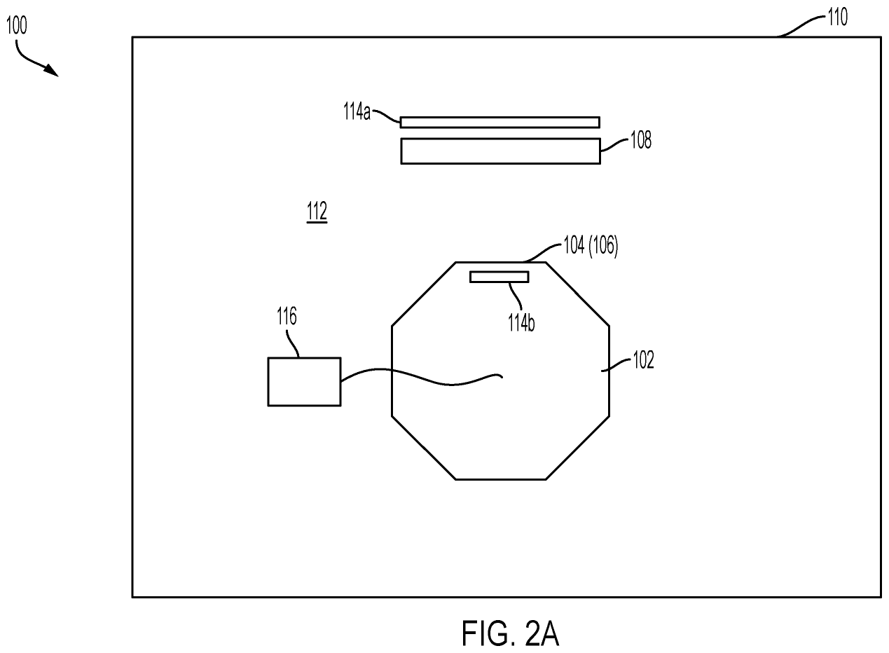

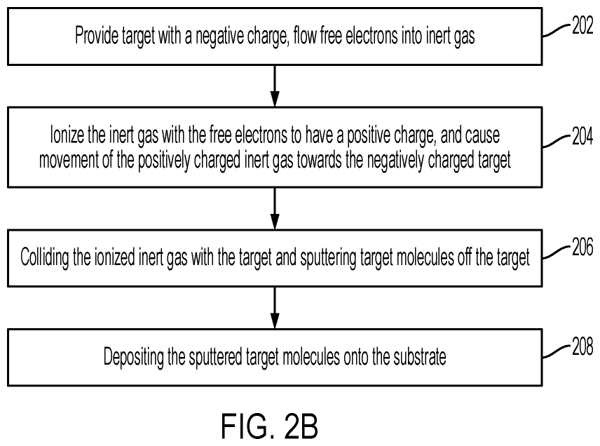

FIG. 2A illustrates an example of a film deposition system 100, according to at least one embodiment. The film deposition system 100 is an example of a drum coater, and includes drum 102, at least one holder 104 attached to, or hung from, the drum 102, at least one substrate mounted to the holder 104, a target 108, a vacuum chamber 110, an inert gas 112, a cathode 114a, an anode 114h, and a motor 116.

In some embodiments, the drum 102 has a polygonal shape. In the depicted example, the drum 102 has a hexagon shape from the depicted plan view, but in other embodiments any appropriate shape can be implemented (e.g., any polygonal shape, any ovoid shape, a circle shape, or any other appropriate shape). The drum is operatively coupled to the motor 116, and the motor 116 is configured to rotate the drum.

In some embodiments, at least one holder 104 is attached to, or hung on, the drum 102. In some embodiments, at least one holder 104 is attached to each side of the drum 102 (e.g., each of the six sides depicted in FIG. 2A). In some embodiments, two or more holders 104 may be attached to a side of the drum 102. The at least one holder 104 is configured to mount one or more substrates 106.

In some embodiments, the substrate 106 may be a substrate for forming a film, or a device or package that includes a film. The substrate may include a substantially flat surface on which target material may be deposited, and may provide a base on which a film of the target material may be developed.

In some embodiments, the target 108 may include a target material that is sputtered on to the substrate 106 to develop the film. The target material may include, for example, a material that includes silicon (e.g. silicon oxynitrite (SiON)), or another material appropriate for sputtering. The film deposition system 100 may be configured as described herein to deposit a film of the target material on the substrate 106. The target may have a sputtering surface that faces the drum 102 from which the target material is sputtered. The target material may be provided with a charge (e.g., may be negatively charged by the cathode 114a, described below).

In some embodiments, the vacuum chamber 110 may encompass at least the drum 102, the holder 104, the substrate 106, the target 108, and the inert gas 112. The vacuum chamber HO may be used to generate and/or maintain a plasma environment of the inert gas 112 (e.g., by controlling a pressure and/or a temperature that the inert gas 112 is subjected to). The inert gas can include, for example, an argon (Ar) gas, or any other appropriate inert gas. In some embodiments, a blend of multiple inert gases may be used. In some embodiments, oxygen or nitrogen may be used (e.g. in combination with the Ar gas, such as in implementations that involve forming an oxide, nitride or oxynitride film).

In some embodiments, the cathode 114a is disposed in the vacuum chamber 110, and is disposed adjacent to, or in contact with, the target 108. In other embodiments, the cathode 114a is disposed outside the vacuum chamber 110, and is electrically connected to the target. The cathode 114a is configured to provide the target material with a negative charge. In some embodiments, the anode 114b is disposed in the vacuum chamber 110, and is disposed adjacent to, or in contact with, the drum 102, the holder 104, and/or the substrate 106. In other embodiments, the anode 114b is disposed outside the vacuum chamber 110, and is electrically connected to the drum 102, the holder 104, and/or the substrate 106. The anode 114b is configured to provide the drum 102, the holder 104, and/or the substrate 106 with a positive charge.

FIG. 2B is a flow chart describing an example of a film deposition method 200 that uses the film deposition system 100, according to at least one embodiment. The film deposition method 200 includes providing the target 108 with a negative charge such that free electrons flow into the inert gas (BLOCK 202), ionizing the inert gas with the free electrons (BLOCK 204), colliding the ionized inert gas with the target to sputter molecules of the target material off the target 108 (BLOCK 206), and depositing the sputtered target molecules on the substrate (BLOCK 208).

In BLOCK 202, the target 108 is provided with a negative charge from the cathode 114a. Free electrons flow from the negatively charged target material into the inert gas 114, which is in a plasma state maintained by the vacuum chamber 110. In BLOCK 204, the free-flowing electrons collide with the outer electronic shell of the inert gas 114 and drive electrons of the outer electronic shell off due to their like electric charge. The molecules of the inert gas 114 become positively charged ions.

In BLOCK 206, the positively charged ions of the inert gas 114 are attracted to the negatively charged target 108, and collide with the target 108 at a sufficient velocity to sputter off particles of the target material from the target 108. In BLOCK 208, the sputtered, negatively charged particles of target material are attracted to the positive charge of the anode 114b, or to the positive charge of the drum 102, the holder 104 or the substrate 106 supplied by the anode 114b, and the sputtered particles (free particles) of target material traverse a portion of the vacuum chamber 110 and are deposited on the substrate 106.

The processes of the BLOCKS 202, 204, 206, and 208 are repeated such that a film of the target material develops on the substrate 106.

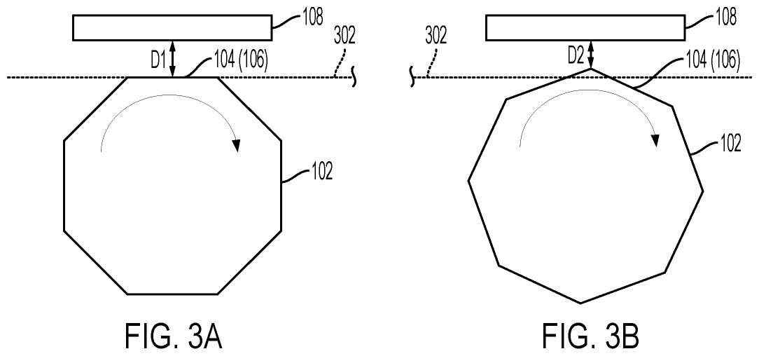

FIG. 3A and FIG. 3B illustrate rotation of the drum 102, according to at least one embodiment. In FIG. 3A, the drum 102 is shown to rotate clockwise in the depicted plan view, and the depiction captures an instant when one side of the drum 102 on which the holder 104 is mounted is substantially parallel to a sputtering surface of the target 108 from which molecules of the target material are sputtered. The depicted position of the drum 102 is one in which a center of the holder 104 is the closest to the target 108 that the center will achieve during rotation of the drum 102. The center of the holder 104 is a distance D1 from the target 108. An imaginary line 302 along which the side of holder 104 facing the target 108 is disposed is shown for reference.

In FIG. 3B, the drum 102 is rotated relative to the position shown in FIG. 3A. The depicted position of the drum 102 in FIG. 3B is one in which an edge of the holder 104 (located at a corner of the drum 102) is the closest to the target 108 that the edge (and the corner) will achieve during rotation of the drum 102. The edge is a distance D2 from the target 108. The distance D2 is smaller than D1, meaning that the edge of the holder 104 will achieve a position closer to the target 108, during the rotation of the drum 102, than the center of the holder 104 will achieve. On average, including all positions achieved during the rotation of the drum 102, the edge of the holder 104 will be closer to the target 108 than will be the center of the holder 104. As discussed above, this can lead to a relatively thicker film being developed at the edge of the holder 104, and a relatively thinner film developing at the center of the holder 104. This can lead to a film having a lower uniformity than is desirable for certain applications.

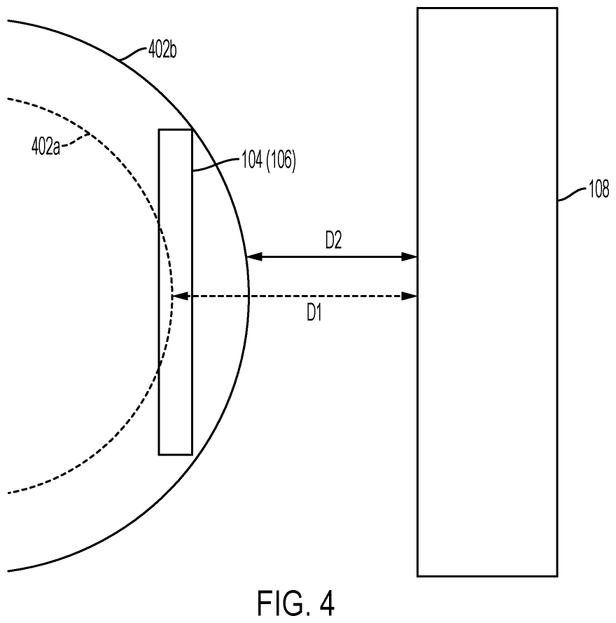

FIG. 4 illustrates respective distances between a center and an edge of the holder 104 and a target 108, according to at least one embodiment. An arc 402a shows a path of a center of the holder 104, and an arc 402b shows a path of an edge of the holder 104 through rotation of the drum 102. The distance D1 is a closest distance achieved between the center of the holder 104 and the target 108 during the rotation of the drum 102. The distance D2 is a closest distance achieved between the center of the holder 104 and the target 108 during the rotation of the drum 102. The arcs 402a and 402b, and the distances m and D2, help show that on average, during the rotation of the drum 102, the edge of the holder 104 will be closer to the target 108 than will be the center of the holder 104, which can lead to a film having a lower uniformity than is desirable for certain applications.

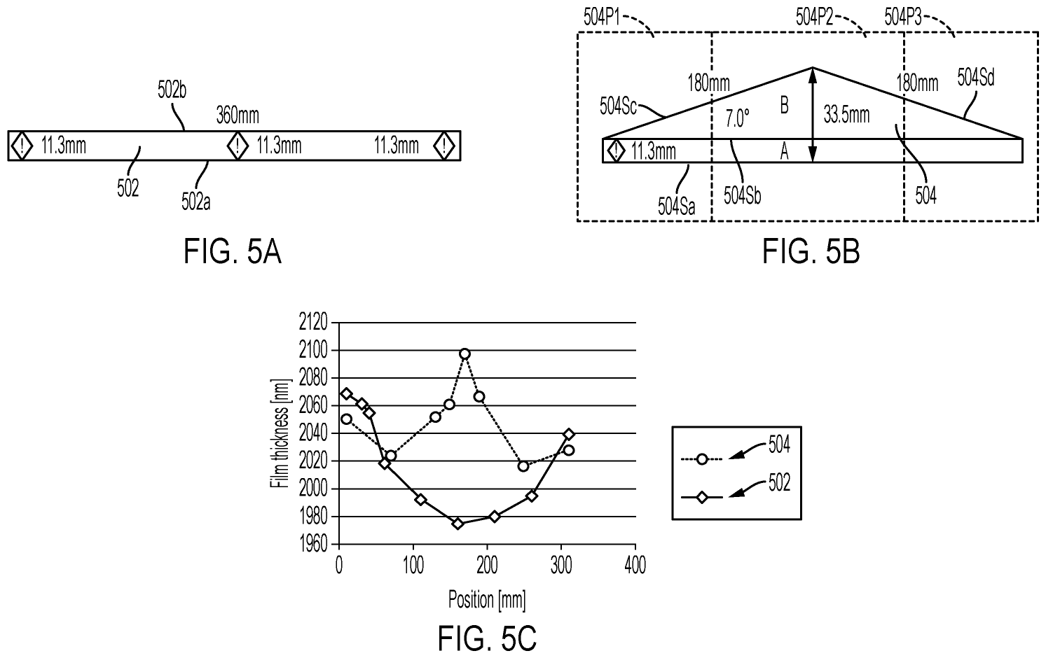

FIG. 5A illustrates a configuration of a comparative holder 502. The comparative holder 502 has a thickness of approximately 11.3 millimeters (mm), and a length of approximately 360 mm. The holder 502 has a first surface 502a that can be attached to a drum 102. The holder 502 has a second surface 502b opposite to the first surface 502a. The second surface 502b can face a target when the holder 502 is implemented in a film deposition system 100, and the second surface 502b is substantially flat. The comparative holder 502 can provide for the development of films that may not be as uniform as desired for certain applications.

FIG. 5B illustrates an example configuration of holder 504, according to at least one embodiment. The holder 504 includes a base portion A having a thickness of approximately 11.3 mm, or a thickness in a range of 9.3 mm to 13.3 mm. The base portion A may have a width approximately equal to, or slightly larger than, 360 mm. The base portion may have a first surface 504Sa that can be attached to a drum 102. The base portion A may have a second surface 504Sb (also referred to as a “top surface” of the base portion) opposite to the first surface 504Sa. The base portion A may have a rectangular prism shape, and may have a rectangular cross-section.

The holder 504 includes a top portion B. The top portion B may have a top surface 504Sc and a top surface 504Sd (which may be referred to as the two faces of the top portion B, as two portions of a single surface). The top surfaces 504Sc and 504Sd may face the target when implemented in the film deposition system 100. Each of the top surfaces 504Sc and 504Sd may have a length of approximately 180 mm. The top surface 504Sc is inclined at an angle relative to the top surface 504Sb of the base portion A (e.g., an angle of approximately 7 degrees), or relative to the surface 504Sa. The top surface 504Sd is also inclined at an angle relative to the top surface 504Sb of the base portion A (e.g., an angle of approximately 7 degrees), or relative to the surface 504Sa. In some embodiments, the inclination may vary between 5-10 degrees or 5-degrees. The top portion B may have a triangular cross-section. In some embodiments, the base portion A of the holder 504 and the upper portion B of the holder 504 are integrally formed, and make up a monolithic object.

The holder 504 may include a first portion 504P1 that is continuous and that includes a first edge of the holder 504, a second portion 504P2 that is continuous and that includes a middle or central section of the holder 504, and a third portion 504P3 that is continuous and that includes a second edge of the holder 504. The first edge of the holder 504 and the second edge of the holder 504 may be opposite to each other. An average thickness of the holder 504 in the first portion 504P1 may be less than an average thickness of the holder 504 in the second portion 504P2. An average thickness of the holder 504 in the third portion 504P3 may be less than an average thickness of the holder 504 in the second portion 504P2. The holder 504 may have a maximum thickness in the second portion 504P2 (e.g., at a center of the holder 504), such as a maximum thickness of approximately 33.5 mm, or a maximum thickness in a range of 30 mm to 37 mm. The holder 504 may have a minimum thickness in the first portion 504P1 or in the third portion 504P3 (e.g., at the first edge of the holder 504 and/or at the second edge of the holder), such as a minimum thickness of approximately 11.3 mm, or a minimum thickness in a range of 9.3 mm to 13.3 mm. In some embodiments, the minimum thickness varies from 10-15 mm and the maximum thickness may vary between 30-40 mm. When the holder 504 is mounted on the drum 102, a distance between the drum 102 and a portion of the top surface 504Sc located at the second portion 504P2 holder is longer than a distance between the drum 102 and a portion of the top surface 504Sc located at the first edge of the holder.

In embodiments in which the holder 504 is thicker at the second (middle) portion 504P2 than at the first and third (edge) portions 504P1 and 504P3, the second portion 504P2 may be brought closer to the target during rotation of the drum 102 than would be the case for a middle of the comparative holder 502, This can help to mitigate the above-described differences between portions of the holder in terms of proximity to the target during rotation of the drum 102. Thus, the holder 504 may be implemented to develop a film having a more uniform thickness than would be developed by the holder 502,

FIG. 5C illustrates experimentally measured thicknesses for films of silicon oxynitride (SiON) developed using the holders shown in FIG. 5A and FIG. 513. As shown in FIG. 5C, the thickness of the film developed using the comparative holder 502 has a roughly “U” shaped profile, and is thicker at edges of the film than at a center of the film. The film developed using the comparative holder 502 has a maximum thickness of approximately 2070 nm, and a minimum thickness of approximately 1970 nm (where a difference between those values is approximately 100 nm), and the comparative holder 502 does not have a sufficient uniformity for certain applications. The thickness of the film developed using the holder 504 is thicker at a center of the film than at edges of the film, and has a maximum thickness of approximately 2100 nm, and a minimum thickness of approximately 2015 nm (where a difference between those values is approximately 85 nm). A thickness uniformity of the film developed using the holder is approximately 2.32%, and a thickness uniformity of the film developed using the holder is approximately 1.97%. As used herein, the term “thickness uniformity” is calculated as follows:

$$thickness uniformity = 100 \% \times \frac{maximum thickness - minimum thickness}{average thickness} \qquad ( 1 )$$

Thus the film developed using the holder 504 is more uniform (has a smaller thickness uniformity) than the film developed using the holder 502.

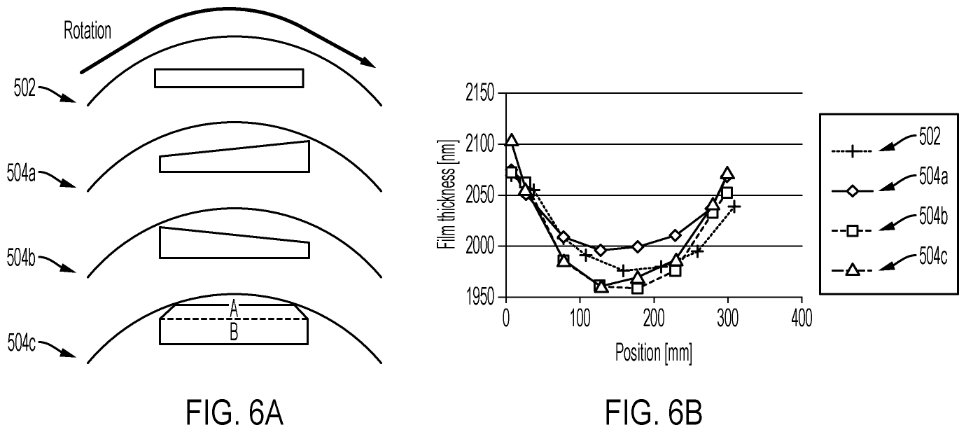

FIG. 6A illustrates example configurations of holders, including holders according to embodiments of the present disclosure. FIG. 6A shows cross-sections or profiles of the comparative holder 502, a holder 504a according to an embodiment of the present disclosure, a holder 504b according to an embodiment of the present disclosure, and a holder 504c according to an embodiment of the present disclosure. The depicted holders are implemented in a film deposition system 100 in which a drum 102 rotates in a given direction of rotation, whereby the depicted holders are moved in the direction of rotation towards the right in the depicted image.

The holder 504a has a substantially flat bottom surface and a top surface that is inclined relative to the bottom surface. The top surface of the holder 504a is inclined relative to the bottom surface such that a right side of the holder 504a (a side in the direction of rotation) is thicker than a left side of the holder 504a (a side opposite to the direction of rotation).

The holder 504h has a substantially flat bottom surface and a top surface that is inclined relative to the bottom surface. The top surface of the holder 504b is inclined relative to the bottom surface such that a left side of the holder 504b (a side opposite to the direction of rotation) is thicker than a right side of the holder 504b (a side in the direction of rotation).

The holder 504c has a substantially flat bottom surface and a top surface has at least three portions: a first portion that is inclined upwards relative to the bottom surface, a second portion that is substantially parallel to the bottom surface, and a third portion that is inclined downwards relative to the bottom surface. The holder 504c may include a base portion A and a top portion B, and the top portion may be in the shape of a trapezoid having a lower surface that is longer than an upper surface.

FIG. 6B illustrates experimentally measured thicknesses for silicon oxynitride (SiON) films developed using the holders shown in FIG. 6A. As shown in FIG. 6B, the profiles of the thicknesses of the films developed using the holders shown in FIG. 6A are roughly “U” shaped. The uniformity, as measured by a difference between a thickest point of the film and a thinnest point of the film, of the developed films is highest for the holder 504a (a difference of approximately 85 nm). The next highest uniformity of the developed film is for the holder 502 (a difference of approximately 100 nm). The next highest uniformity the developed film is for the holder 504b (a difference of approximately 120 nm). The next highest uniformity the developed film is for the holder 504c (a difference of approximately 150 nm). A thickness uniformity of the holder 502 is approximately 2.32%. A thickness uniformity of the holder 504a is approximately 1.99%. A thickness uniformity of the holder 504b is approximately 3.54%. A thickness uniformity of the holder 504c is approximately 2.88%. Thus, the holder 504a develops a film that is more uniform than the comparative holder 502.

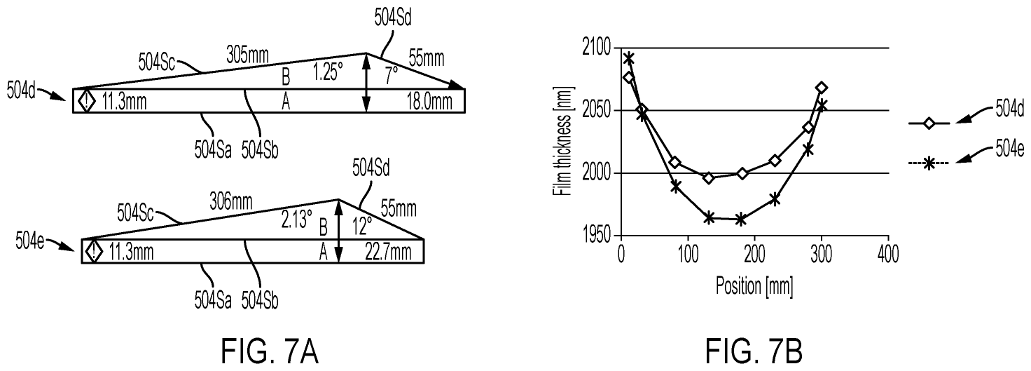

FIG. 7A illustrates example configurations of holders 504d and 504e, according to embodiments of the present disclosure. The holders 504d and 504e, like the holder 504 shown in FIG. 5B, each include a respective base portion A having a thickness of approximately 11.3 mm, or a thickness in a range of 9.3 mm to 13.3 mm. The base portion A may have a width approximately equal to, or slightly larger than, 360 mm. The base portion may have a first surface 504Sa that can be attached to a drum 102. The base portion A may have a second surface 504Sb (also referred to as a “top suffice” of the base portion) opposite to the first surface 504a. The base portion A may have a rectangular prism shape, and may have a rectangular cross-section.

The holder 504d includes a top portion B. The top portion B may have a triangular cross-section. In some embodiments, the base portion A of the holder 504d and the upper portion B of the holder 504d are integrally formed, and make up a monolithic object. The top portion B may have a top surface 504Sc and a top surface 504Sd (which may be referred to as the two faces of the top portion B, or as two portions of a single surface of the top portion B). The top surfaces 504Sc and 504Sd may face the target when implemented in the film deposition system 100. The top surface 504Sc may have a length of approximately 305 mm. In other embodiments, the top surface 504Sc may have a length between 250 mm and 350 mm. The top surfaces 504Sd may have a length of approximately 55 mm. The top surface 504Sc is inclined at an angle relative to the top surface 504b of the base portion A (e.g., an angle of approximately 1.25 degrees, or an angle between 1 degree and 2 degrees, or an angle between 0 degrees and 3 degrees), or relative to the surface 504Sa. The top surface 504Sd is also inclined at an angle relative to the top surface 504b of the base portion A (e.g., an angle of approximately 7 degrees, or an angle between 0 degrees and 20 degrees, or 1 degree and 20 degrees), or relative to the surface 504Sa. A thickest portion of the holder 504d may be approximately 18.0 mm (e.g., may have a thickness between 16 mm and 20 mm).

The holder 504e includes a top portion B. The top portion B may have a triangular cross-section. In some embodiments, the base portion A of the holder 504e and the upper portion B of the holder 504e are integrally formed, and make up a monolithic object. The top portion B may have a top surface 504Se and a top surface 504Sd (which may be referred to as the two faces of the top portion B, or as two portions of a single surface). The top surfaces 504Sc and 504Sd may face the target when implemented in the film deposition system 100. The top surface 504Sc may have a length of approximately 306 mm. The top surfaces 504Sd may have a length of approximately 55 mm. The top surface 504Sc is inclined at an angle relative to the top surface 504b of the base portion A (e. g., an angle of approximately 2.13 degrees, or an angle between 1 degree and 2 degrees, or an angle between 0 degrees and 3 degrees), or relative to the surface 504Sa. The top surface 504Sd is also inclined at an angle relative to the top surface 504b of the base portion A (e.g., an angle of approximately 12 degrees, or an angle between 0 degrees and 20 degrees, or an angle between 1 degree and 20 degrees), or relative to the surface 504Sa. A thickest portion of the holder 504e may be approximately 22.7 mm (e.g., may have a thickness between 20.7 mm and 24.7 mm).

FIG. 7B illustrates experimentally measured thicknesses for silicon oxynitride (SiON) films developed using the holders shown in FIG. 7A. The film developed using the holder 504d has a maximum thickness of approximately 2080 nm, and a minimum thickness of approximately 1995 nm (where a difference between those values is approximately 85 nm). The film developed using the holder 504e has a maximum thickness of approximately 2090 nm, and a minimum thickness of approximately 1965 nm (where a difference between those values is approximately 125 nm. A thickness uniformity of the holder 504d is approximately 1.99%. A thickness uniformity of the holder 504e is approximately 3.21%. Thus, the holder 504d develops a film having a higher uniformity than the holder 504e.

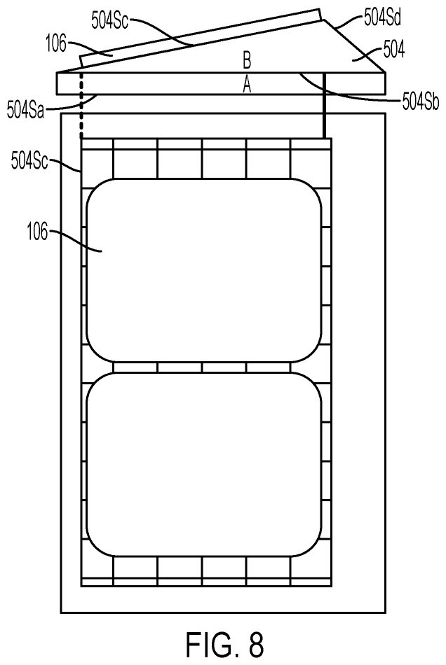

FIG. 8 illustrates an example of substrates 106 disposed on a holder 504, according to embodiments of the present disclosure. The holder 504 includes a base portion A. The base portion may have a first surface 504Sa that can be attached to a drum 102. The base portion A may have a second surface 504Sb (also referred to as a “top surface” of the base portion) opposite to the first surface 504a. The base portion A may have a rectangular prism shape, and may have a rectangular cross-section.

The holder 504 includes a top portion B. The top portion B may have a triangular cross-section. In some embodiments, the base portion A of the holder 504 and the upper portion B of the holder 504 are integrally formed, and make up a monolithic object. The top portion B may have a top surface 504Sc and a top surface 504Sd (which may be referred to as the two faces of the top portion B). The top surfaces 504Sc and 504Sd may face the target when implemented in the film deposition system 100. The top surfaces 504Sc and 504Sd are inclined at respective angles relative to the top surface 504b of the base portion A, or relative to the surface 504Sa.

In some embodiments, one or more substrates 106 are mounted to the top surface 504Sc, and no substrates 106 are mounted to the top surface 504Sd. In such embodiments, the top surface 504Sd may be referred to as “dead space.” In other embodiments, one or more substrates 106 may be mounted to the top surface 504Sd (e.g., in addition to, or alternatively to, one or more substrates 106 being mounted to the top surface 504Sc).

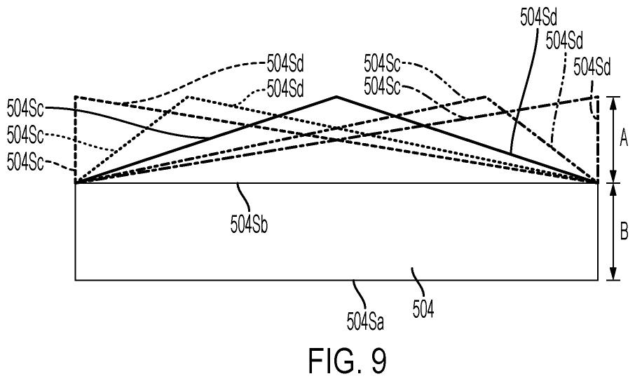

FIG. 9 illustrates example configurations of surfaces of a holder 504, according to embodiments of the present disclosure. The holder 504 may be the holder shown in FIG. 8, and may include a base portion A, and a top portion B, and may have surfaces 504Sa, 504Sb, 504Sc, 504Sd. As shown in FIG. 9, the surfaces 504Sc and 504Sd may be inclined at various angles relative to the surface 504Sb, or relative to the surface 504Sa. Disclosed herein are ranges of angles for those surfaces, and lengths for those surfaces, that provide for improved and unexpected results, including development of a film having improved uniformity relative to holders (e.g., the holder 102) that do not implement such angles or lengths. For example, the surface 504Sc may be inclined at an angle in a range of 1 degree to 90 degrees (e.g., in a range of degree to 2 degrees) relative to the surface 504Sb or 504Sa. The surface 504Sd may be inclined at an angle in a range of 1 degree to 90 degrees (e.g., in a range of 1 degree to 20 degrees) relative to the surface 504Sb or 504Sa. A sum of the length of the surface 504Sc and 504Sd may sum to 400 mm or less. Such configurations may provide for developing a film having a thickness uniformity of 2% or less, or a film wherein a difference in thickness between a thickest part of the film and a thinnest part of the film is less than 90 mm. In some embodiments, the holder 504 is configured to expose the substrate 106 to free particles of a target material such that a film of the target material is grown on the substrate 106, wherein a difference in thickness between a thickest part of the film and a thinnest part of the film is less than 90 mm.

As used herein and in the appended claims, singular articles such as “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any appropriate orientation or manner, provided that the merits of embodiments of this disclosure are not deviated from by such an arrangement.

While this specification contains specific implementation details, these should not be construed as limitations on the scope of What may be claimed, but rather as descriptions of features specific to particular embodiments. Certain features described in this specification in the context of separate embodiments can also be implemented in combination in a single embodiment. Conversely, various features described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

A surface being described as “substantially flat,” unless expressly defined otherwise, means a surface having a greatest variation from an average height or position being less than or equal to a certain amount (e.g., less than or equal to 10% of the average thickness, less than or equal to 5% of the average thickness, less than or equal to 4% of the average thickness, less than or equal to 3% of the average thickness, less than or equal to 2% of the average thickness, or less than or equal to 1% of the average thickness), or a surface for which a displacement between a highest point and a lowest point of the surface is no greater than 3 mm, no greater than 2 mm, no greater than 1 mm, or no greater than 0.5 mm.

As used herein, two surfaces being “substantially parallel” means having angles of inclination that differ from each other by no more than 5 degrees, no more than 4 degrees, no more than 3 degrees, no more than 2 degrees, or no more than 1 degree.

As used herein, the terms “substantially” and “approximately” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms refers to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, the term “substantially” or “approximately” equal in reference to two values refers to a ratio of the two values being within a range between and inclusive of 0.9 and 1.1.

As used herein, a shape being “asymmetric” means a shape having no line of symmetry. As used herein, a “line of symmetry” refers to an imaginary line that bisects an object into a first portion and a second portion, wherein a reflection of the first portion over the imaginary line results in the first portion being substantially superimposed on the second portion (where “substantially superimposed” can mean that an aggregate area of non-overlapped parts of the first portion and the second portion is: less than or equal to 10% of an aggregate area of overlapped parts of the first portion and the second portion, less than or equal to 5% of the aggregate area of the overlapped parts of the first portion and the second portion, less than or equal to 4% of the aggregate area of the overlapped parts of the first portion and the second portion, less than or equal to 3% of the aggregate area of the overlapped parts of the first portion and the second portion, less than or equal to 2% of the aggregate area of the overlapped parts of the first portion and the second portion, or less than or equal to 1% of the aggregate area of the overlapped parts of the first portion and the second portion).

Amounts, ratios, and other numerical values are sometimes presented herein in a range format. It is to be understood that such a range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure, as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A system for film deposition, comprising:
a drum;
a motor configured to rotate the drum in a direction of rotation;
a target comprising a target material; and
a holder attached to the drum, the holder configured to accommodate a substrate and to expose the substrate to free particles of the target material sputtered from the target,
wherein the holder has an asymmetric shape.

2. The system according to claim 1, wherein:
the holder has a first surface and a second surface opposite to the first surface,
the first surface is attached to the drum,
the holder comprises:
a first portion that is continuous and that includes a first edge of the holder; and
a second portion, and
the second portion of the holder is thicker than the first portion of the holder.

3. The system according to claim 2, wherein the direction of rotation is a direction extending from the first portion of the holder to the second portion of the holder.

4. The system according to claim 2, wherein the second portion of the holder is a central portion, and the central portion of the holder is attached to and contacts the drum.

5. The system according to claim 2, wherein the holder comprises a third portion that is continuous and that includes a second edge of the holder opposite to the first edge of the holder.

6. The system according to claim 1, wherein the holder has a first surface attached to the drum and a second surface, and the second surface is inclined at an angle between 0 degrees and 3 degrees relative to the first surface.

7. The system according to claim 1, wherein the drum has a polygon shape having a plurality of edges and a plurality of corners, and the motor is configured to rotate the drum such that a shortest distance between one of the corners and the target during one revolution of the drum is less than a shortest distance between one of the edges and the target during the one revolution of the drum.

8. A system for film deposition, comprising:
a drum;
a motor configured to rotate the drum in a direction of rotation;
a target comprising a target material; and
a holder attached to the drum, the holder configured to accommodate a substrate and to expose the substrate to free particles of the target material sputtered from the target, wherein:
the holder has a first surface and a second surface opposite to the first surface, and a first edge and a second edge opposite to the first edge,
the holder comprises a first portion that is continuous and that includes the first edge of the holder, a second portion, and a third portion that is continuous and that includes the second edge of the holder, and the second portion is located between the first portion of the holder and the third portion of the holder, and
a distance between the drum and a portion of the second surface located at the second portion of the holder is longer than a distance between the drum and a portion of the second surface located at the first edge of the holder.

9. The system according to claim 8, wherein the second portion of the holder is thicker than the first portion of the holder, and the second portion of the holder is thicker than the third portion of the holder.

10. The system according to claim 8, wherein:
the second surface of the holder is inclined, at a first angle, between the first portion of the holder and the second portion of the holder,
the second surface of the holder is inclined, at a second angle different from the first angle, between the second portion of the holder and the third portion of the holder,
the first surface of the holder is substantially flat, and
the first angle and the second angle are relative to the first surface of the holder.

11. The system according to claim 10, wherein the first angle is larger than 0 degrees and less than 3 degrees.

12. The system according to claim 8, wherein a distance along the second surface between the first edge of the holder and a thickest portion of the second portion of the holder is between 250 millimeters (mm) and 350 mm.

13. The system according to claim 10, wherein the second angle is between 0 degrees and 20 degrees.

14. The system according to claim 8, further comprising the substrate, wherein the substrate is disposed on the first portion of the holder and the second portion of the holder.

15.-20. (canceled)

21. A drum coater, comprising:
a holder configured to accommodate a substrate and to expose the substrate to free particles of a target material, wherein:
the holder comprises a first portion having a top surface at 0 degrees from a horizontal, and a second portion disposed on the top surface of the first portion,
the second portion has a first surface inclined at a first angle relative to the top surface of the first portion, and a second surface inclined at a second angle relative to the top surface of the first portion,
the first angle is in a range of 90 degrees to 1 degree, and
the second angle is in a range of 90 degrees to 1 degree.

22. The drum coater according to claim 21, wherein the first angle is in a range of 1 degree to 2 degrees.

23. The drum coater according to claim 21, wherein the second angle is in a range of 1 degree to 20 degrees.

24. The drum coater according to claim 21, wherein the holder is configured to expose the substrate to the free particles of the target material such that a film of the target material is grown on the substrate, the film having a thickness uniformity of 2% or less.

25. The drum coater according to claim 21, wherein a length of the first surface of the second portion and a length of the second surface of the second portion sum to 400 millimeters (mm) or less.
